(19) United States
(12) Patent Application Publication
(10) Pub. No.: US 2005/0103979 A1
(43) Pub. Date: May 19, 2005

(54) Temporal source analysis using array detectors

(75) Inventor: Gerald Heigel, Granada Hills, CA (US)

Correspondence Address: DARBY & DARBY P.C., P. O. BOX 5257, NEW YORK, NY, 10150-5257, US

(73) Assignee: Photo Research, Inc., Chatsworth, CA (US)

(21) Appl. No.: 10/988,293

(22) Filed: Nov. 12, 2004

Related U.S. Application Data
(60) Provisional application No. 60/520,020, filed on Nov. 13, 2003.

(51) Int. Cl. H01L 27/00

(52) U.S. Cl. 250/208.1

(57) ABSTRACT

A method and apparatus for temporal source analysis using array detectors is provided. The invention allows synchronization of an imaging device with a temporally discontinuous illumination source, for example, a raster scan source or a strobed source. Moreover, a fast scan of signals through an array detector may be used to determine signals or data of interest, and to thence process only the data of interest to determine such temporal measurements. A signal analyzer and method are disclosed for accurately determining the timing, for example the ON time, of a timing source using an array detector. Temporal source analysis and synchronization are automatically performed using a fast scan technique for reading data from the array detector.

### FIELD OF THE INVENTION

This disclosure relates generally to the field of signal detection, and in particular to array detectors for determining signal characteristics of a signal source such as temporally discontinuous signal source.

### DESCRIPTION OF RELATED ART

Data processing has improved, for example, by increasing the speed of microprocessors to handle large amounts of data. Typically, both relevant and irrelevant data are processed together, since high microprocessor speeds may allow such combined data handling with some sacrifice in overall processing speed. However, the efficiency of data processing may be greatly increased by determining and processing only the relevant data for a given computation.

In the field of signal timing and detection, typically both relevant data, corresponding to a signal, and irrelevant data, including noise, are processed together. In order to make accurate temporal measurements and/or synchronize devices to a timing source, such as a raster or strobed source, it is necessary to first accurately determine the time period of the emissions of the source, such as the “ON time”. In the case of raster source devices, such as monitors, televisions, and cathode ray tube (CRT) devices, the determination of the time period involves synchronizing measurements to a frame rate of the source. In the case of strobed sources, determination of the time period involves synchronizing to the strobe rate and/or measuring the ON time of the source.

Heretofore, the processing of signals during signal detection has been relatively inefficient since irrelevant signals are typically processed with relevant signals. A need exists for an improved signal detection and analysis technique for efficiently determining temporal measurements of timing sources such as raster and strobe sources.

Techniques for providing images over time often take advantage of a characteristic known as persistence of vision. If images change faster than the eye and brain can process the images, the images perceived by the eye and brain do not represent the actual changes in the images at every point in time. Rather, the eye and brain perceive a relatively continuous changes to an image even if the images are discontinuous over short periods of time.

Generation, storage, transmission, and reproduction of images over time, for example, motion picture or video images, use persistence of vision advantageously to reduce the amount of information needed. Rather than attempting to process and display an image continuously and having to provide information relating to every point in the image at every moment in time, a series of discrete images is presented at intervals that are within the limits of persistence of vision. For example, a series of instantaneous images may be presented at a rate of many images per second, such as 24 or 30 images per second. The eye and brain do not perceive the result as a series of discrete images, but rather as a single, continuously changing image.

While motion pictures may be produced using a series of complete images, with each complete image displayed as a whole at the appropriate time in the presentation of the series of images, each of the images of a series of images need not be a complete image presented at a specific moment in time. Rather, scanning display devices, such as a television or video monitor, take advantage of persistence of vision even to display each image of a series of images.

A scanning display device may utilize a raster scanning technique whereby an illumination source scans across an image to illuminate various parts of the image at various times. Since this scanning occurs rapidly, the eye and brain perceive the entire image as being present simultaneously.

While these motion picture and scanning techniques may result in perceptions of a single, continuous, dynamic image when viewed directly with the eye, attempts to observe such images and displays using other imaging devices that obtain a series of images, such as a video camera, can result in substantial degradation of the images unless the imaging device is synchronized with the images or displays. The degradation can include dark or light regions of the image, bright spots on the image, and flickering. Similar degradation can occur when using an imaging device to observe images illuminated with a stroboscopic illumination source.

Thus, a technique is needed to synchronize an imaging device with a temporally discontinuous illumination source.

### SUMMARY OF THE INVENTION

It is recognized herein that an array detector may be used for obtaining synchronization with a temporally discontinuous signal source, for example, a raster scan source or a strobed source. Moreover, a fast scan of signals through an array detector may be used to determine signals or data of interest, and to thence process only the data of interest to determine such temporal measurements.

A signal analyzer and method are disclosed for accurately determining the timing, for example the ON time, of a timing source using an array detector. Temporal source analysis and synchronization are automatically performed using a fast scan technique for reading data from the array detector.

### BRIEF DESCRIPTION OF THE DRAWINGS

FIG. 1 is a block diagram illustrating one embodiment of a signal analyzer according to the invention.

FIG. 2 is a flow diagram illustrating one embodiment of a process according to the invention.

FIG. 3 is a block diagram illustrating one embodiment of a signal analyzer utilizing a linear array detector according to one embodiment of the invention.

FIG. 4 is a block diagram illustrating an area array detector having an area of interest.

FIG. 5 is a block diagram illustrating an area array detector having had all rows preceding the area of interest shifted through the area array.

FIG. 6 is a block diagram illustrating an area array detector having had a row within the area of interest shifted into a serial shift register.

FIG. 7 is a block diagram illustrating an area array detector having had a first pixel of the area of interest transferred to an output.

FIG. 8 is a block diagram illustrating an area array detector having had a second pixel of the area of interest transferred to an output.

FIG. 9 is a block diagram illustrating an area array detector and its associated serial shift register having been cleared.

FIG. 10 is a flow diagram illustrating a process for synchronizing an imaging device with a temporally discontinuous illumination source.

FIG. 11 is a flow diagram illustrating a process for sampling a portion of the pixels of an array detector.

### DESCRIPTION OF THE PREFERRED EMBODIMENTS

The invention provides a method and apparatus for synchronizing an imaging device with a temporally discontinuous illumination source. By providing synchronization, the invention allows an imaging device to obtain images from a temporally discontinuous illumination source, such as a raster scan display, for example a television or video monitor, a stroboscopic illumination source, an interrupted source, or any source having a time-varying nature.

The imaging device may comprise an array detector for detecting electromagnetic radiation. For example, the array detector may be a one-dimensional, or linear, array detector or a two-dimensional, or area, array detector. One example of such a detector is an array detector that utilizes charge transfer to collect data from the array, such as a charge-coupled device (CCD).

A CCD typically comprises an array of photosensitive or electromagnetically sensitive cells that build up charge in relation to the amount of electromagnetic energy to which they have been exposed. The cells can be used to provide data for each picture element (pixel) in an image. A pixel represents data needed to reconstruct a specific point or very small area of an image. The cells of the CCD are organized such that charge contained in the cells can be shifted through array to a readout register. The readout register is also organized with cells for storing charge such that charge can be shifted through the readout register to provide at an output a signal representative of a the charge shifted through the readout register.

The signal may be converted from the form of a series of charges to another form, such as a time-varying voltage or current signal using an amplifier or other electronic circuit. The signal may be converted from an analog representation of the data to a digital representation of the data using an analog-to-digital converter. The digital representation of the signal may be processed using a processor and stored in memory. The same processor or a separate processor may be used to control the operation of the detector array, including the shifting of charge through the detector array and through the readout register, as well as the data conversion process.

One step for providing accurate temporal measurements and/or synchronizing an imaging device to a temporally discontinuous illumination source involves accurately determining a time period during which the illumination source is providing illumination. For raster scan illumination sources, for example video monitors, televisions, cathode ray tube devices, etc., this involves synchronizing measurements of the rate at which the raster scan illumination source completes illumination of all areas of the display screen. For stroboscopic illumination sources, this involves synchronizing to the strobe rate and/or measuring the time during which the stroboscopic illumination source is illuminated (i.e., the “ON” time of the source).

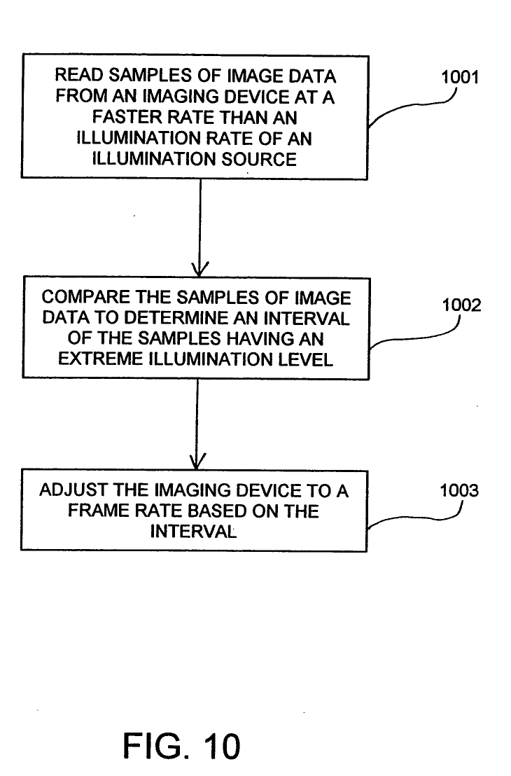

FIG. 10 is a flow diagram illustrating a process for synchronizing an imaging device with a temporally discontinuous illumination source. The process comprises a step 1001 of reading samples of image data from an imaging device at a faster rate than an illumination rate of an illumination source. The process compares the samples of image data to determine an interval of the samples having an extreme illumination level, such as a minimum or maximum illumination level, in step 1002. In step 1003, the process adjusts the imaging device to a frame rate based on the interval determined in step 1002.

Since the illumination rate of a temporally discontinuous illumination source may not be known in advance, the invention provides a technique for obtaining information about the illumination rate of the illumination source. To provide adequate temporal resolution to obtain meaningful information about the illumination rate of the illumination source, a plurality of samples of image data are read from the imaging device over time at a faster rate than the illumination rate of the illumination source. Since the illumination rate may not be known in advance, the samples of image data are read from the imaging device at a rate greater than an expected range of the illumination rate or at a rate substantially faster than any maximum illumination rate that might be expected.

By taking samples of image data at relatively high rate, sequences of individual samples can be compared to determine which samples were taken while the illumination source was providing a maximal illumination intensity, which samples were taken while the illumination source was providing a minimal illumination intensity, and which samples may have been taken at some intermediate illumination intensity. By comparing these samples taken at different phases of the illumination cycle, information relating to the illumination rate can be determined. These comparisons can be performed on entire images taken as a whole, on entire images using a pixel-by-pixel comparison, or on specific portions of images or points within an image.

Even if the rate at which samples are taken using the imaging device is not high enough to provide data at every moment in time, samples taken over several illumination cycles can be compared to allow interpolation of data based on samples taken during similar temporal offsets of different illumination cycles. This technique is especially useful if the nature of the illumination source and the timing of the illumination rate vary little over a period of time sufficient for several samples to be taken. By performing comparisons over several illumination cycles to determine the precise timing of maximal illumination intensities and minimal illumination intensities, and by comparing intervening perimaximal and periminimal illumination intensities to determine the number of cycles occurring between the measured timing of the maximal and minimal illumination intensities, both the frequency and phase of the illumination cycles can be precisely determined.

Based on this precise frequency and phase information, the processor controlling the imaging device can adjust the imaging device to operate at a frame rate that is precisely synchronized with the illumination rate. The imaging device can be adjusted to obtain an image while the illumination source is illuminated and to process the image, for example by shifting the charge representing the image, while the illumination source is not illuminated. Alternatively, because of the precision of the synchronization, the imaging device can be adjusted to obtain an image beginning or ending at any phase of the illumination cycle.

The imaging device may be adjusted to operate at the same frequency as that of the illumination rate or at a rate that is a submultiple of the illumination rate. A submultiple of the illumination rate is a rate which is a fraction of the illumination rate where the denominator of the fraction is an integer. For example, rates that are one half, one third, one fourth, or one fifth of the illumination rate are submultiples of the illumination rate. Thus, operating an imaging device at a submultiple of the illumination rate allows each frame of data provided by the imaging device to have a duration that spans one or an integer number of illumination cycles of the illumination source. Consequently, the imaging device is used to provide a uniformity of exposure to the illumination source from frame to frame that avoids the image degradation of prior art techniques.

While samples of image data may be read from an imaging device at a high rate, a certain amount of time is needed to shift the image data through the array detector and through the readout register and to convert the data from an analog form to a digital form. One technique for reducing the amount of time need to process the image data involves accumulating data from multiple pixels and converting the accumulated data from analog form to digital form. Since the accumulated data represent multiple pixels, the image data can be converted from analog form to digital form with fewer conversion cycles of the analog-to-digital converter, thereby reducing the amount of time needed to process the image data. This process is referred to as pixel binning, as the pixels are “binned” together before conversion.

Another technique can be used to reduce the amount of time needed to process the image data. A portion of the array detector can be defined as a region of interest. Pixels within the region of interest can be processed, while pixels outside of the region of interest can be ignored or shifted through the array detector and/or readout register without performing data conversion or processing operations on them. Since fewer pixels are converted or processed, the amount of time needed to process the image data is reduced.

Pixel binning can also be applied to the pixels within the region of interest, thereby reducing even further the amount of time needed to process the image data. By limiting image data provided at the output to image data from a region of interest and by using pixel binning to process the image data from multiple pixels in a single operation, very high frame rates can be achieved.

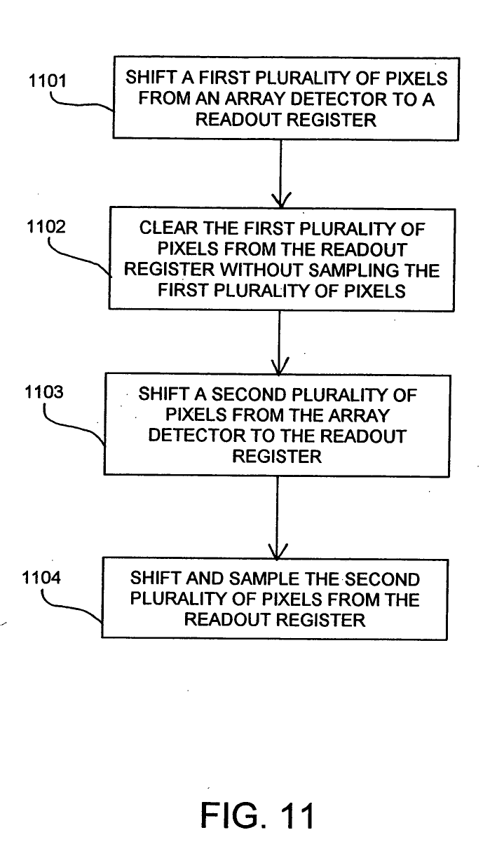

FIG. 11 is a flow diagram illustrating a process for sampling a portion of the pixels of an array detector. The process comprises the step 1101 of shifting a first plurality of pixels from an array detector to a readout register. The process clears the first plurality of pixels from the readout register without sampling the first plurality of pixels in step 1102. By avoiding the time needed to sample the first plurality of pixels, for example, the time needed to perform analog-to-digital conversion of the first plurality of pixels, the process provides increased speed, as the shifting can be performed at a high rate.

In step 1103, the process shifts a second plurality of pixels from the array detector to the readout register. In step 1104, the process shifts and samples the second plurality of pixels from the readout register. The shifting and sampling of step 1104 may be performed at a high rate or at a lower rate than the rate used in step 1101. Use of a lower rate provides increased sensitivity for the second plurality of pixels.

The array detector may also comprise a third plurality of pixels beyond the second plurality of pixels. If the third plurality of pixels does not include relevant image data, the third plurality of pixels may be ignored and the array detector and readout register cleared to allow another cycle of the process to begin.

Selection of a technique for increasing the rate at which image data is read from an imaging device may be based on a variety of criteria. For example, the type of illumination source and the pattern of illumination of the array detector may be used to select a technique.

If the illumination is concentrated or focused on a particular portion of the array detector of if the illumination spectra are spread across the array detector, the portion of the array with the greatest sensitivity can be sub-sampled in order to increase readout rate and reduce data analysis requirements.

If the illumination is dispersed evenly over the entire array, sub-sampling may be used to increase speed or pixel binning may be used to increase speed and sensitivity.

One method for increasing the rate at which image data is obtained from an array detector involves controlling the array detector in a continuous “fast scan” mode that rapidly scans or shifts image data from the array detector without regard to collection of data from portions of the array that are not of interest. Image data from a region of interest is sub-sampled at a slower “normal” rate. The use of differing rates for reading pixels outside of a region of interest and pixels within a region of interest allows collection and analysis of image data from the region of interest much faster than was previously possible.

Some imaging devices employ a photosensitive readout register that is exposed to the illumination source. In such imaging devices, if the readout register comprises the region of interest, the readout register may be read to provide image data at an output without the need to perform scanning or shifting operations on the array detector.

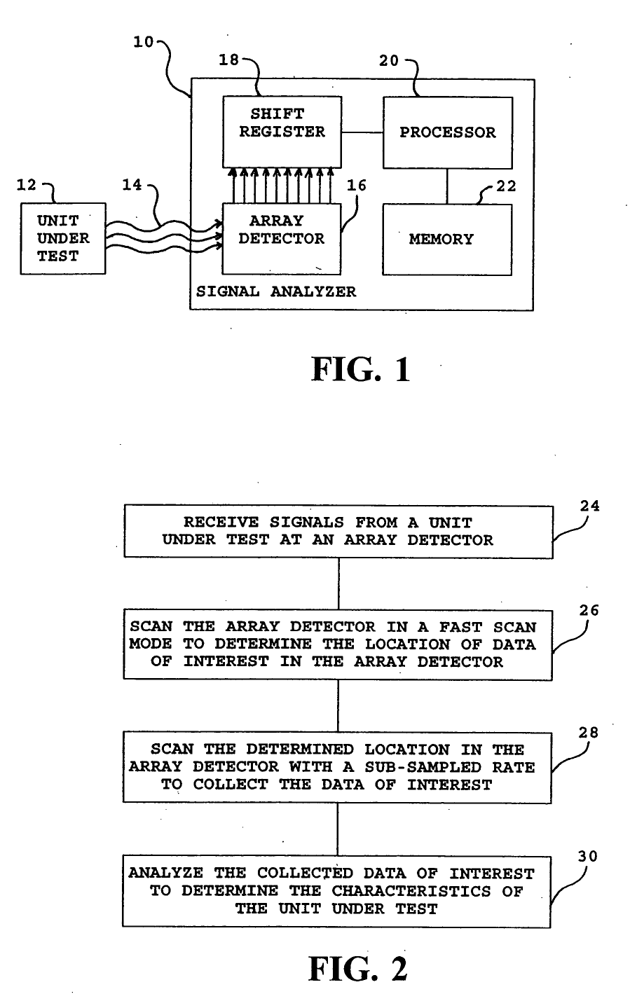

FIG. 1 is a block diagram illustrating one embodiment of a signal analyzer 10 according to the invention. The signal analyzer 10 comprises an array detector 16, a shift register 18, a processor 20, and a memory 22. A unit under test 12 provides signals 14 incident upon array detector 16. The array detector responds to the signals 14 and provides a plurality of outputs to shift register 18. Shift register 18 provides output data to processor 20. Processor 20 stores output data from shift register 18 in memory 22. Processor 20 also controls the operation of shift register 18 and array detector 16.

Referring in specific detail to the drawings, with common reference numbers identifying similar or identical elements, steps, and features, as shown in FIG. 1, the present disclosure describes a signal analyzer 10 and method for accurately determining the ON-time of a timing source such as a unit under test (UUT) 12. The signals 14 from the UUT 12 are detected using an array detector 16, which may include charge-coupled devices (CCDs), photodiode arrays, etc. The array detector 16 may be connected to or may include an analog-to-digital (A/D) converter for generating digital data from the signals 14.

Temporal source analysis and synchronization are automatically performed using a fast scan technique described herein using a readout register 18, such as a shift register, for reading data generated by the array detector 16. For example, a digitized form of the signals 14 may be generated by the A/D converter of the array detector 16, and the digitized signals are then loaded to the readout register 18, for example, using a clocking procedure and/or a sampling of the digitized signals from the array detector 16.

A processor 20 then proceeds to analyze the data in the readout register 18. The processor 20 may be a digital signal processor (DSP) or other computing devices and/or microprocessors, such as the 68332 microprocessor available from “MOTOROLA”.

In a preferred embodiment, the processor 20 has a sufficient processing speed to perform the disclosed temporal analysis of the signals 14 from the UUT 16.

A memory 22 may be included for storing the determined ON-time of the UUT 12, as well as for storing an operating program executed by the processor 20 to perform the temporal source analysis methods. In addition, the readout register 18 may be incorporated into the memory 22. Alternatively, the processor 20 may include the readout register 18 and/or the memory 22 on a single integrated circuit (IC).

The operating program for controlling the processor 20 of the signal analyzer 10 may be compiled or assembled from source code written, for example, in C, C++, or assembly language.

Alternatively, the signal analyzer 10 may be constructed primarily or solely in hardware/firmware; for example, as an IC using very large scale integration (VLSI) to include the array detector 16, the readout register 18, and A/D converter, etc.

FIG. 2 is a flow diagram illustrating one embodiment of a process according to the invention. In step 24, signals from a unit under test 12 are received at an array detector 16. In step 26, processor 20 scans array detector 16 in a fast scan mode to determine the location of data of interest in the array detector 16. The scanning process of step 26 includes transfer of data from array detector 16 to shift register 18 and from shift register 18 to processor 20.

In step 28, processor 20 scans the determined location in the array detector 16 at a sub-sampled rate to collect the data of interest. The scanning process of step 28 includes transfer of data from array detector 16 to shift register 18 and from shift register 18 to processor 20. In step 30, processor 20 analyzes the collected data of interest to determine the characteristics of the unit under test 12.

As shown in FIG. 2, the method of use of the signal analyzer 10 includes the steps of receiving the signals 14 from the unit under test 12 at the array detector 16 in step 24, scanning the array detector 16 in a fast scan mode in step 26 to determine the location of data of interest in the array detector 16, scanning the determined location in the array detector 16 with a sub-sampled rate to collect the data of interest in step 28, and analyzing the collected data of interest in step 30 using the processor 20 to determine the characteristics of the unit under test 12.

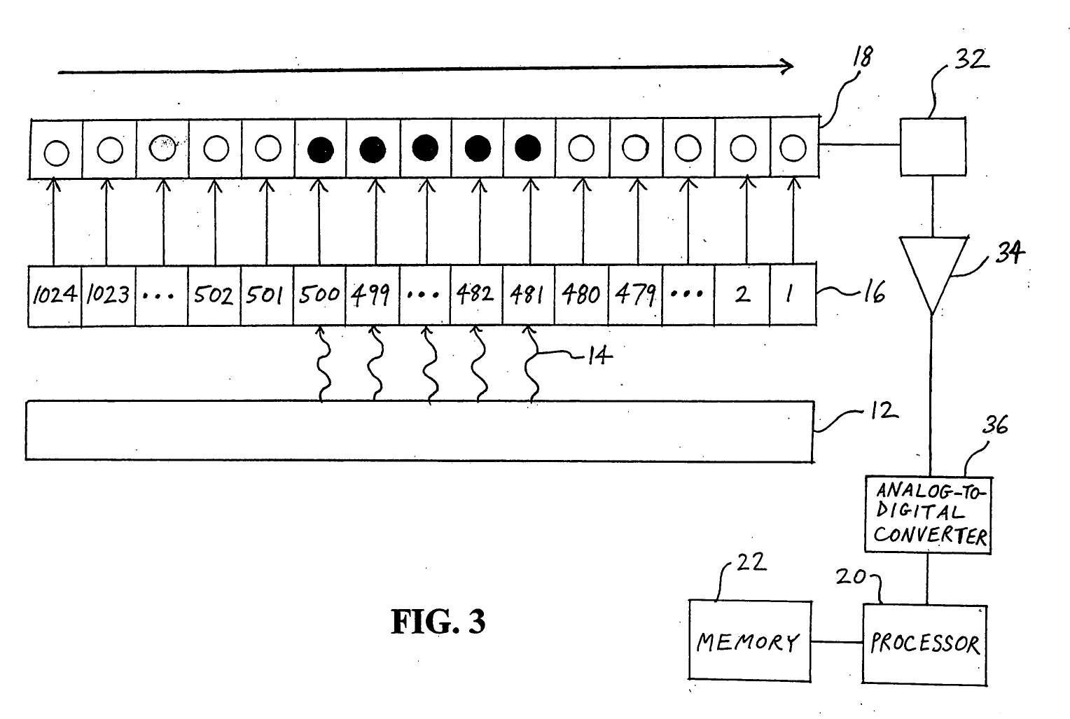

The array detector 16 may be either a linear array detector or an area array detector, in which a plurality of detection elements, such as shown in FIGS. 3-7, are arranged in a linear or rectangular array, or in other shapes such as circular and three-dimensional configurations, for receiving the signals 14. The array detector 16 is run in a continuous fast scan mode, in which a fast scan is defined herein as the running of the array detector 16 in a mode to rapidly scan an image out of the array detector 16 without regard to the collection of data from portions of the detection elements of the array detector 16 which may not be of interest.

The portions of the detection elements having detected signals which are of interest are then sub-sampled as a predetermined normal rate less than the rate of the fast scan. Such selective scanning rates permit the collection and analysis of a portion of the data by sub-sampling at a collection and analysis rate which is typically much faster than possible using detectors operating under normal operation.

The method of FIG. 2 determines an area of interest in step 26 in the context of the type of source of emissions and how the emissions are focused on the array detector 16. In step 26, the method determines if the image is focused on a portion of the array elements, or alternatively the spectra are spread across the array elements. If so, the portion of the array detector 16 with relatively high sensitivities are sub-sampled to increase the readout rate and to reduce the data analysis requirements.

If the image is determined in step 26 to not be focused; that is, if the image is dispersed generally evenly over the entire set of array elements, the image is sub-sampled for increased speed. Alternatively, multiple pixels may be accumulated, “binned” or sorted into categories, and sampled with resolutions of a few or a single data element. Such sub-sampling with relatively few data element provides a combination of increased speed and sensitivity.

For raster scan sources, it is necessary that the array detector 16, readout register 18, and processor 20 receive and process data faster than the line rate of the source of the signals 14; that is, the UUT 12. For strobed scan sources, the array detector 16, readout register 18, and processor 20 are to process data at a sufficient rate to resolve the ON-time of the source of the signals 14 within a predetermined measurement accuracy. The scan rate or read-out rate of the array detector 16 is typically predetermined, and so may be determinative of the overall processing of the signals 14.

Linear Array Detector

For an array detector 16 configured as a linear array detector, the array elements of the array detector 16 may be read for data using a single transfer of the image to the readout register 18. The sampling of the data from all or a portion of the array elements is then performed using a relatively fast rate. If the image is determined in step 26 to not be focused; that is, if the image is dispersed generally evenly over the entire set of array elements, the image is sub-sampled for increased speed or binned to increase sensitivity.

Using data processing techniques known in the art, the image from several pixels may be accumulated, binned, and converted/analyzed by the processor 20 to be treated as a single element, which provides a combination of increased speed and sensitivity.

FIG. 3 is a block diagram illustrating one embodiment of a signal analyzer 10 utilizing a linear array detector 16 according to one embodiment of the invention. Signals 14 from unit under test 12 are incident upon array detector 16, which is, in this embodiment, a linear, or one-dimensional, array detector. Each cell or pixel of linear array detector 16 is in communication with a respective cell of readout register 18. For example, in a charge-coupled device, each cell or pixel of linear array detector 16 can transfer charge to a respective cell of readout register 18. Readout register 18 is a shift register that allows charges stored in cells to be shifted toward an output or binning cell 32. Binning cell 32 allows accumulation of charge from multiple cells or pixels to provide a binning capability. Alternatively, Binning cell 32 can be configured to avoid accumulation of charge from multiple cells or pixels if binning is not desired.

Amplifier 34 amplifies the charge or signal present at binning cell 32 and may convert the charge level to a voltage level or other representative signal level, for example a current level. Analog-to-digital converter 36 receives the signal level provided by amplifier 34 and provides a digital representation to processor 20. Processor 20 stores the digital representation in memory 22.

In the example illustrated in FIG. 3, a 1024×1 linear array detector is used as the array detector 16 for detecting the signals 14 in step 24. The area of interest is determined in step 26, for example, to be pixels 481-500. The readout register 18 is cleared, and the image is shifted or loaded into the readout register 18. Pixels 1-480 are shifted out, and pixels 481-500 are then sampled in step 28. The remaining pixels 501-1024 are ignored. The pixels 481-500 may not even be read out of the shift register 18 except to clear the readout register 18 to read pixels 481-500.

Step 26 may be repeated to process any remaining pixels of interest until the area of interest is determined, for example, by the exceeding of a predetermined threshold by the pixels. The sample rate is then increased by approximately ((524*PRT)+(1004*DCT)), where PRT is the pixel readout time, and DCT is the data conversion time, and the pixels of interest are scanned as in step 28 to collect the data of interest. If pixels 481-500 are binned instead of sampled, individually, the sample rate is further increased by approximately (19*DCT) while also increasing the sensitivity dramatically. The data from the sampled pixels 481-500 are then processed in step 30 to determined the characteristics of the UUT 12, such as a strobe rate.

Area Array Detector

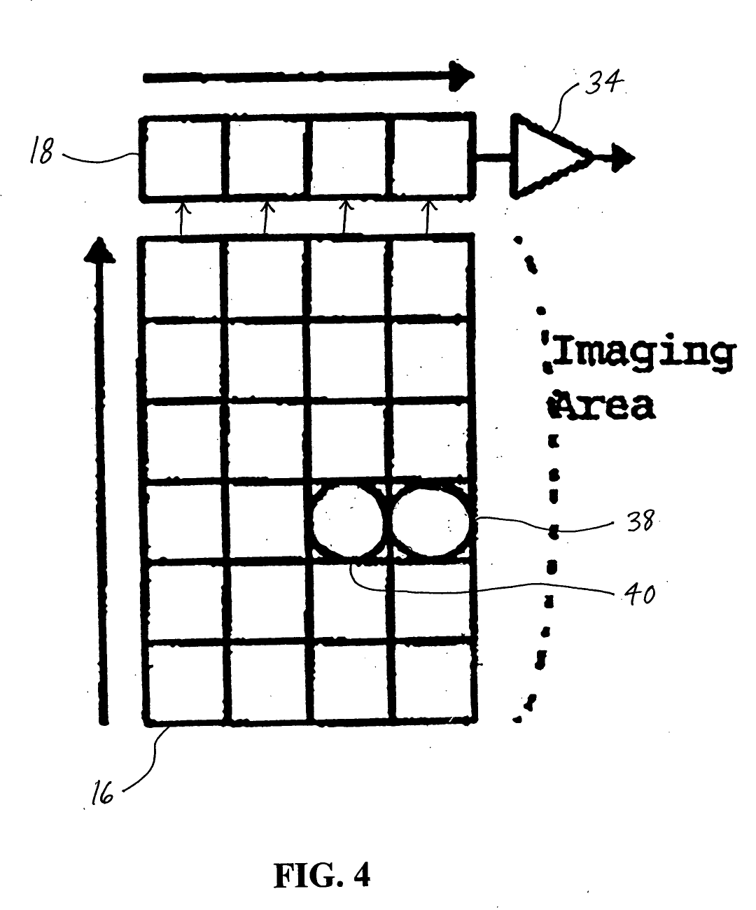

FIG. 4 is a block diagram illustrating an area array detector 16 having an area of interest. The area of interest comprises pixels 38 and 40. Area array detector 16 is organized in a rectilinear manner which can be understood as having a plurality of one-dimensional rows or columns. Pixels 38 and 40 are located in the same row, but in different columns. It is understood that an area of interest may span multiple rows and column and may be defined in any desired pattern within area array detector 16.

Area array detector 16 provides the ability to shift rows upward so that the rows may be transferred to readout register 18 in a serial manner. Readout register 18 provides one cell for each column of area array detector 16.

Readout register 18 provides the ability to shift cells toward an output coupled to amplifier 34. By shifting the cells of readout register 18, data may be provided in a serial manner at the output of amplifier 34.

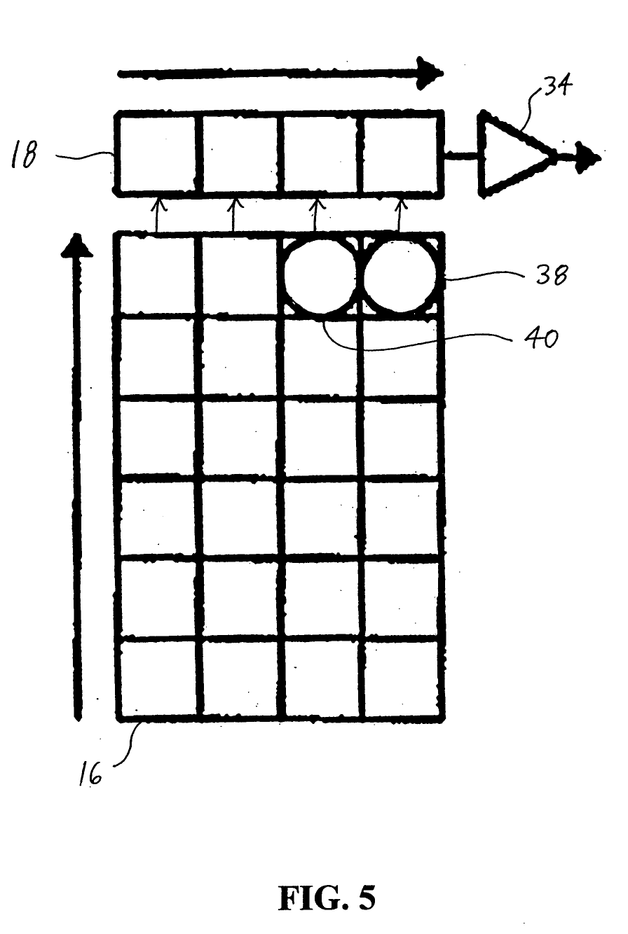

FIG. 5 is a block diagram illustrating an area array detector having had all rows preceding the area of interest shifted through the area array. As compared with FIG. 4, the row containing pixels 38 and 40 of FIG. 5 has been shifted up three rows. Thus, pixels 38 and 40 are ready to be transferred into the corresponding cells of readout register 18.

Since the three rows formerly above the row in which pixels 38 and 40 are located were not included within the area of interest, those three rows were shifted upward without the need to shift readout register 18 or process the pixels contained in those three rows through amplifier 34. Thus, substantial time savings are provided by avoiding unnecessary processing of pixels outside the area of interest.

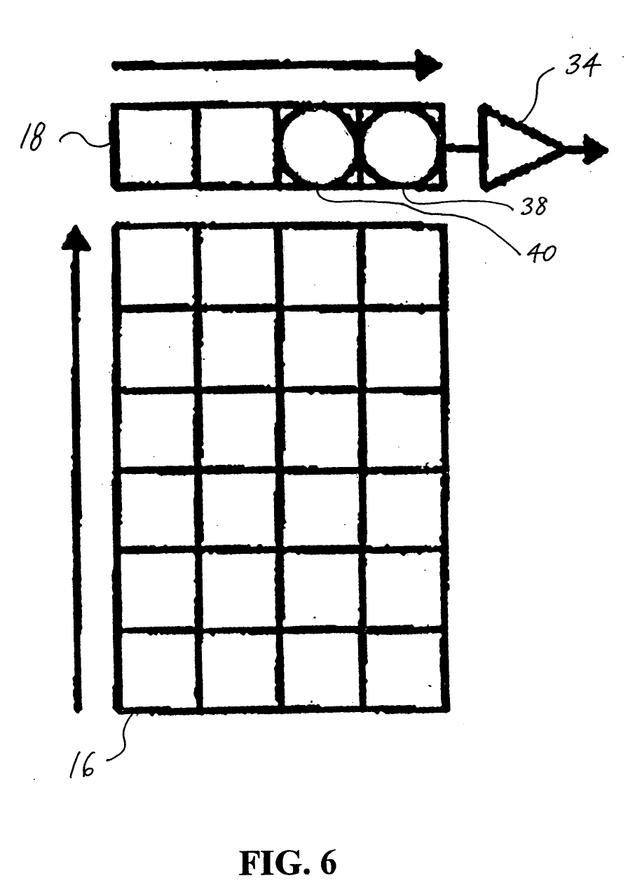

FIG. 6 is a block diagram illustrating an area array detector having had a row within the area of interest shifted into a serial shift register. As compared with FIG. 5, the row containing pixels 38 and 40 has been transferred from the top row of area array detector 16 to readout register 18.

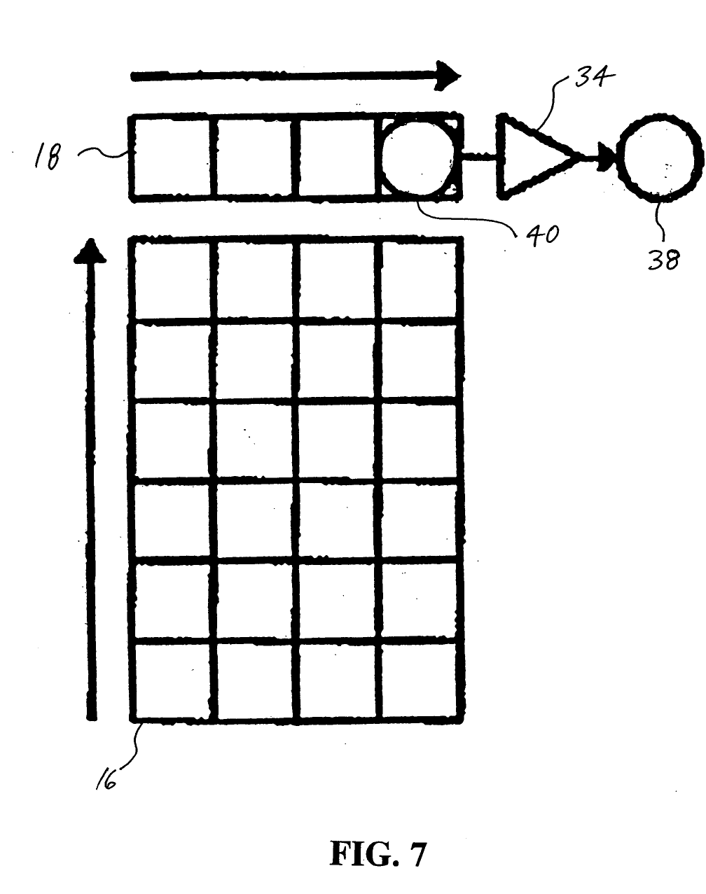

FIG. 7 is a block diagram illustrating an area array detector having had a first pixel of the area of interest transferred to an output. As compared with FIG. 6, pixel 38 has been amplified by amplifier 34 and provided as data at the output of amplifier 34. Since amplifier 34 may be used to convert data from one form to another, for example from a charge level to a voltage level, the data representative of pixel 38 at the output of amplifier 34 may be of any suitable form, such as voltage, current, charge, or other physical representation.

The data stored in the cells of readout register 18 have been shifted to the right. Thus, pixel 40 is shifted one cell to the right of its former position and is ready for to be processed by amplifier 34.

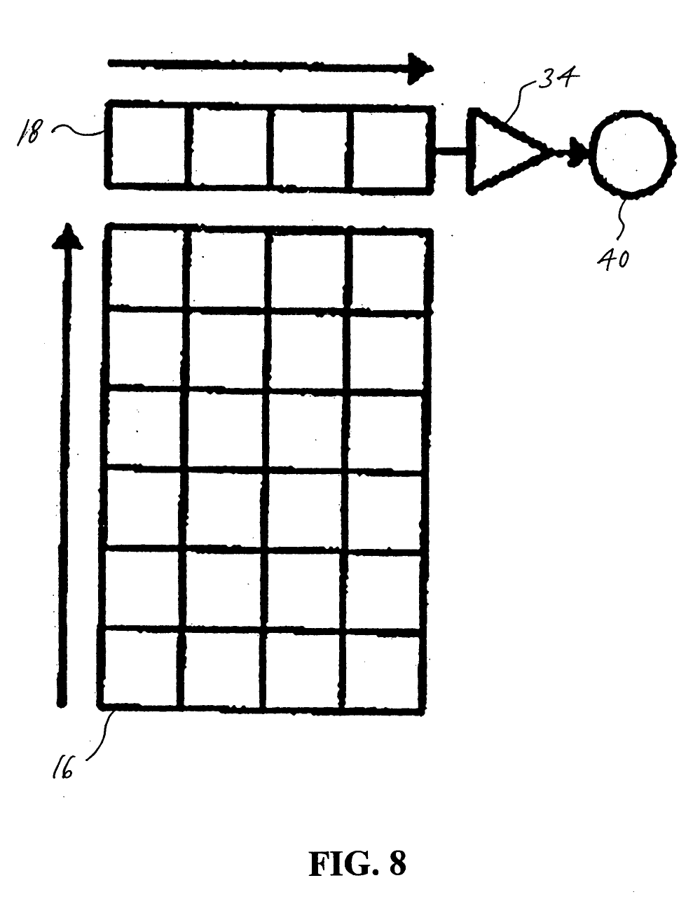

FIG. 8 is a block diagram illustrating an area array detector having had a second pixel of the area of interest transferred to an output. As compared with FIG. 7, pixel 40 has been amplified by amplifier 34 and is provided as data at the output of amplifier 34. Since amplifier 34 may be used to convert data from one form to another, for example from a charge level to a voltage level, the data representative of pixel 40 at the output of amplifier 34 may be of any suitable form, such as voltage, current, charge, or other physical representation.

Since the pixels that had been to the left of pixel 40 and that are now still in readout register 18 are not within the area of interest, it is not necessary to continue shifting pixels through readout register 18 and processing the pixels through amplifier 34. Rather, readout register 18 may be cleared. Thus, substantial time savings are realized by avoiding processing of pixels not within the area of interest.

Also, since all pixels within the area of interest have been shifted out of area array detector 16 and processed through readout register 18 and amplifier 34, area array detector 16 may be cleared without concern for rows that formerly existed below the row in which pixels 38 and 40 were located. Clearing area array detector 16 without processing rows of pixels outside of the area of interest provides substantial time savings.

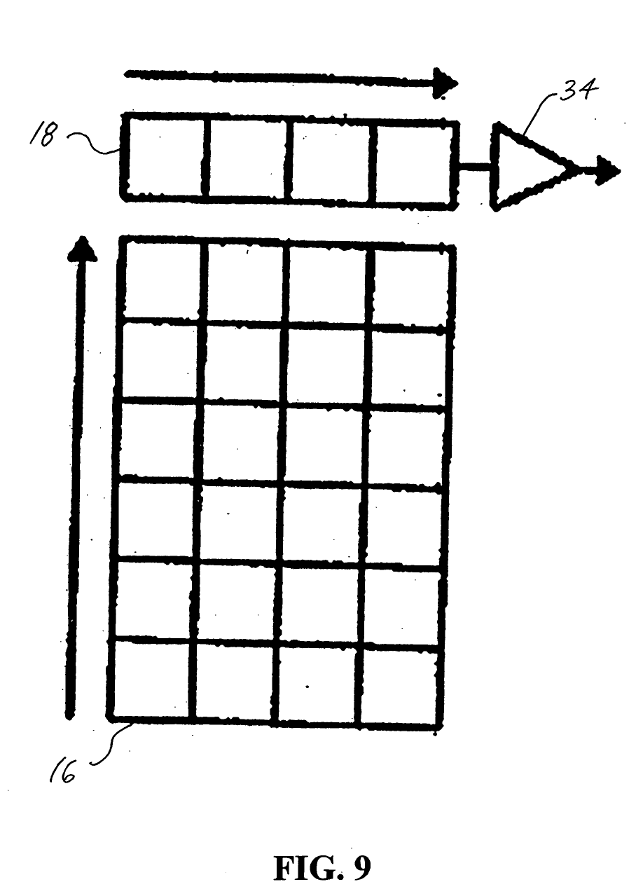

FIG. 9 is a block diagram illustrating an area array detector and its associated serial shift register having been cleared. Pixels 38 and 40, as well as any other pixels that may have been stored in area array detector 16 or readout register 18 have been cleared from these elements. Thus, area array detector 16 and readout register 18 are cleared so that their cells or pixels have values representative of the absence of signals 14 from unit under test 12. Area array detector 16 is, therefore, ready to receive additional signals 14 from unit under test 12.

Since the output of amplifier 34 may be coupled to an analog-to-digital converter that may require significant amounts of time to perform its conversion function, not only does the invention save time and increase processing speed by avoiding processing of pixels or cells outside of the area of interest through readout register 18 and amplifier 34, but the invention also significantly reduces the time and increases the processing speed by avoiding the need for time-consuming analog-to-digital conversion of data representative of pixels outside the area of interest.

For an array detector 16 being, for example, an area array such as a rectangular array of detector elements, if the image may be focused on the first row of array elements of the area array detector 16 while leaving the remainder of the array detector 16 unexposed; that is dark or unaffected, the area array detector 16 may be treated as a linear array detector with every row transfer being used to detect the image intensity. Otherwise, operation of an area array detector 16 is similar to operation of the linear array detector as described above but has the added dimension of multiple row to form an image frame.

As shown in FIG. 4, for a 4×6 array detector as a full frame device requires a short integration period between frame transfers to allow image integration. With frame transfer devices, the integration period is automatically introduced during the frame readout time. With area array detectors, the rows which are not of interest are shifted out without performing any sampling of the data therein. In fact, multiple rows may be shifted up or down and may never shifted out until the readout register 16 needs to be cleared to sample data from the rows of interest.

For the 4×6 area array detector shown in FIG. 4, 24 array elements arranged in rows and columns for receiving an image. The readout register 18 is a serial shift register. The pixels 38, 40 illustrate an image area of interest. In this example, the image area; that is, the area of interest is the third row of pixels. As shown in FIG. 5, the first 3 rows are shifted out to the serial readout register 18. As shown in FIG. 6, the serial register is cleared, and the image row is shifted up into the readout register 18. As shown in FIG. 7, pixel 38 is sampled, and then, as shown in FIG. 8, pixel 40 is sampled. The remaining pixels in the fourth row need not be read out. As illustrated in 1 FIG. 9, the remaining rows are shifted out to complete clearing the array elements, and the readout register 18 is also cleared.

After a relatively short integration period, this process is repeated until the time between thresholds is determined.

In actuality, the size of the array is typically much larger than shown in FIGS. 4-9, which causes the increase in the image capture rate to be much more significant. For example, when the method described above for FIGS. 4-9 is applied to a 1024×1024 array detector, and the area of interest is the first 16 pixels of row 1, the sequence of stepson include clearing the readout register, shifting the first row of the image down to the readout register, and sampling the first 16 pixels as in a linear array. The remaining 1008 pixels are ignored, and do not have to be read out. The remaining 1023 rows are shifted out to clear the array. These steps are repeated until the thresholds are determined. The sample rate is increased by approximately ((1023*1024)+1008)*PST, in which the PST is the pixel sample time includes the readout time and data conversion time (DCT). If the 16 sampled pixels are binned instead of sampled individually, the sample rate is further increased by approximately 15*DCT which also increases the sensitivity of the array detector.

While the disclosed signal analyzer system and method is particularly shown and described herein with reference to the preferred embodiments, it is to be understood that various modifications in form and detail may be made without departing from the scope and spirit of the present invention. Accordingly, modifications such as any examples suggested herein, but not limited thereto, are to be considered within the scope of the present invention.

1. A method for synchronizing an imaging device with a temporally discontinuous illumination source comprising the steps of:
reading a plurality of samples of image data from said imaging device at a faster rate than an illumination rate of said illumination source;
comparing said plurality of samples of said image data to determine an interval of said plurality of samples having an extreme illumination level;
adjusting said imaging device to a frame rate based on said interval.

2. The method of claim 1 wherein said frame rate is a submultiple of said illumination rate.

3. The method of claim 2 wherein said frame rate equals said illumination rate.

4. The method of claim 1 wherein said temporally discontinuous illumination source is a raster scan illumination source.

5. The method of claim 4 wherein said raster scan illumination source is a cathode ray tube device.

6. The method of claim 1 wherein said temporally discontinuous illumination source is a stroboscopic illumination source.

7. The method of claim 1 wherein said extreme illumination level is a relatively low illumination level.

8. The method of claim 1 wherein said extreme illumination level is a relatively high illumination level.

9. The method of claim 1 wherein said step of reading a plurality of samples of image data further comprises:
binning a plurality of pixels.

10. The method of claim 1 wherein said step of reading a plurality of samples of image data further comprises:
transferring and sampling a first plurality of pixels; and
transferring, but not sampling, a second plurality of pixels.

11. The method of claim 1 wherein said step of reading said plurality of samples of image data from said imaging device comprises:
reading said plurality of samples of image data from an array detector.

12. The method of claim 11 wherein said step of reading said plurality of samples of image data from said array detector comprises:
reading said plurality of samples of image data from a one-dimensional array detector.

13. The method of claim 11 wherein said step of reading said plurality of samples of image data from said array detector comprises:
reading said plurality of samples of image data from a two-dimensional array detector.

14. The method of claim 11 wherein said step of reading said plurality of samples of image data from said array detector comprises:
reading said plurality of samples of image data from a charge-coupled device.

15. Apparatus comprising:
an imaging device for providing an image based on illumination received from an illumination source, said illumination source operating at an illumination rate;
a controller for controlling said imaging device to operate in at a fast scan rate relatively faster than said illumination rate, for determining a synchronized scan rate that is a submultiple of said illumination rate, and for adjusting said imaging device to operate at said synchronized scan rate.

16. The apparatus of claim 15 wherein said controller controls binning of a plurality of pixels while said imaging device is operating at said fast scan rate.

17. The apparatus of claim 15 wherein said controller controls the transfer and sampling of a first plurality of pixels of said imaging device and the transfer without sampling of a second plurality of pixels of said imaging device.

18. The apparatus of claim 15 wherein said synchronized scan rate is equal to said illumination rate.

19. The apparatus of claim 15 wherein said imaging device comprises an array detector.

20. The apparatus of claim 19 wherein said array detector comprises a one-dimensional array detector.

21. The apparatus of claim 19 wherein said array detector comprises a two-dimensional array detector.

22. The apparatus of claim 15 comprises a charge-coupled device.

23. The apparatus of claim 15 wherein said illumination source comprises a raster scan illumination source.

24. The apparatus of claim 23 wherein said raster scan illumination source comprises a cathode ray tube device.

25. The apparatus of claim 15 wherein said illumination source comprises a stroboscopic illumination source.

26. A method comprising the steps of:
shifting a first plurality of pixels from an array detector to a readout register;
clearing said first plurality of pixels from said readout register without sampling said first plurality of pixels;
shifting a second plurality of pixels from said array detector to said readout register;
shifting and sampling said second plurality of pixels from said readout register.

27. The method of claim 26 wherein said step of shifting and sampling said second plurality of pixels from said readout register further comprises:
binning two or more of said second plurality of pixels prior to sampling said two or more of said second plurality of pixels.

28. The method of claim 26 wherein said step of shifting a first plurality of pixels from an array detector to a readout register further comprises:
shifting said first plurality of pixels from a one-dimensional array detector to said readout register.

29. The method of claim 26 wherein said step of shifting a first plurality of pixels from an array detector to a readout register further comprises:
shifting said first plurality of pixels from a two-dimensional array detector to said readout register.

30. The method of claim 26 wherein said step of shifting a first plurality of pixels from an array detector to a readout register further comprises:
shifting said first plurality of pixels from a charge-coupled device to said readout register.

31. Apparatus comprising:
an array detector comprising a first plurality of pixels and a second plurality of pixels;
a controller for controlling transfer of said first plurality of pixels and said second plurality of pixels, wherein said controller causes transfer without sampling of said first plurality of pixels and said controller causes transfer and sampling of said second plurality of pixels.

32. The apparatus of claim 31 wherein said controller controls binning of two or more of said second plurality of pixels prior to sampling of said two or more of said second plurality of pixels.

33. The apparatus of claim 31 wherein said array detector comprises a one-dimensional array detector.

34. The apparatus of claim 31 wherein said array detector comprises a two-dimensional array detector.

35. The apparatus of claim 31 wherein said array detector comprises a charge-coupled device.
